(19) United States
(12) Patent Application Publication
(10) Pub. No.: US 2016/0002766 A1
(43) Pub. Date: Jan. 7, 2016

(54) HIGH TEMPERATURE LOW FRICTION COATING LAYER AND THE METHOD OF THE SAME

(71) Applicant: Hyundai Motor Company, Seoul (KR)

(72) Inventors: Sung-Chul Cha, Seoul (KR); Seung-Hyun Hong, Seoul (KR); Moon-Ki Bae, Hwaseong (KR)

(73) Assignee: Hyundai Motor Company

(21) Appl. No.: 14/569,298

(22) Filed: Dec. 12, 2014

(30) Foreign Application Priority Data
Jul. 3, 2014 (KR) 10-2014-82831

(51) Int. Cl. C23C 14/06; C23C 14/02; B22C 9/12; C23C 14/22; F01D 5/02; B22C 9/06; C23C 14/34; C23C 16/44

(52) U.S. Cl. CPC C23C 14/0641; C23C 14/34; C23C 14/022; C23C 16/44; C23C 14/22; F01D 5/02; B22C 9/061; B22C 9/12; F05D 2220/40; F05D 2230/90; F05D 2300/174

(57) ABSTRACT

Disclosed are a coating layer having excellent low-friction ability at a high temperature and a method of forming the coating layer. The high-temperature low-fiction coating layer may improve heat resistance, fatigue resistance, low-friction ability, and seizure resistance of the turbine wheel of a turbocharger and the parts sliding at a high temperature in the exhaust system of an engine, improve turbo-lag, and improve durability of the high-temperature parts in the exhaust system of an engine. The high-temperature low-friction coating layer includes: a CrN bonding layer 110 disposed on a nitrified base material 100; a TiAlCrYN nano-multi-support layer 120 disposed on the CrN bonding layer 110 to achieve heat resistance, fatigue resistance, wear resistance, and toughness of the coating layer; and a TiAlCrYCN nano-multi-function layer 130 disposed on the TiAlCrYN nano-multi-support layer 120 to achieve heat resistance, oxidation resistance, seizure resistance, toughness, and low-friction ability of the coating layer.

### CROSS-REFERENCE TO RELATED APPLICATIONS

This application claims priority under 35 U.S.C. §119 to Korean Patent Application No. 10-2014-82831, filed on Jul. 3, 2014, in the Korean Intellectual Property Office, the disclosure of which is incorporated herein by reference in its entirety.

### TECHNICAL FIELD

The present invention relates to a coating layer with low friction at a high temperature and a method of forming the coating layer. The coating layer may improve heat resistance, fatigue resistance, low-friction ability, and seizure resistance of high-temperature sliding parts such as a turbocharger and a turbine wheel, or aluminum die-casting molds by applying a CrN bonding layer on a base material, a TiAlCrYN nano-multi-support layer on the CrN bonding layer, and a TiAlCrYCN nano-multi-function layer on the TiAlCrYN nano-multi-support layer.

### BACKGROUND

Current vehicle industry pursues development of various environment-friendly vehicles and aims at mounting a turbocharger and an exhaust gas recirculation (EGR) to increase combustion efficiency of an engine by increasing the temperature of an exhaust gas and reduce exhaust amount of carbon dioxide to about 50 g/km or by about 35 to 50% until 2020 by reducing NOx and downsizing an engine.

The turbocharger, a device recycling an exhaust gas for driving power, is a part for improving fuel efficiency and reducing the weigh or size of an engine by supplying high-density compressed air into a cylinder to improve performance of the engine. The parts of a turbine may be required to resist high-temperature heat and high pressure, because they are frequently exposed to a high-temperature exhaust gas at a temperature of about 800 to 1,050° C.

In particular, efficiency of an engine may be improved by reducing 50% of the weight of a turbine wheel of a turbocharger, turbo-lag may be improved by about 30% or greater due to early shifting enabled by rapidly increasing torque of the turbine wheel, and accordingly, the operation with higher gears engaged may be extended.

TiAl-based materials have been used for a coating layer to reduce the weight of a turbine wheel, but their heat resistance, crack resistance, high-temperature fatigue resistance, and toughness are not sufficient. Accordingly, increasing the thickness of the turbine wheel and decreasing the exhaust temperature have been required in order to compensate these properties.

Vehicle manufacturers have been substantially using aluminum parts to reduce weight to improve competitiveness concerned with improvement of fuel efficiency and exhaust gas regulations. Accordingly, aluminum die-casting molds have been frequently used but the aluminum die-casting molds may require improvement in high-level properties due to harsh conditions including continuous high loads and large shocks. However, their lifespan may be influenced by mold materials, mold design, work conditions, and thermal treatment and surface treatment of the molds. Further, heat checking may be caused and developed by a thermal shock, seizure and wear may be caused by molten aluminum, and thermal softening of materials and coatings may be caused by work at a high temperature, such that the hardness and properties of the aluminum die-casting molds may decrease.

Therefore, development of a coating layer with improved seizure resistance, wear resistance, low-friction ability, heat resistance, and oxidation resistance for molds has been progressed actively. For example, nitrides or carbides based on titanium (Ti) and chromium (Cr) may be used, and particularly, titanium aluminum nitride (TiAlN) or aluminum chromium nitride (AlCrN) has been used for coating layers of those aluminum die-casting molds in the related art.

TiAlN (Titanium aluminum nitride), however, has heat resistance not sufficient to be used for a coating layer of aluminum die-casting molds that are exposed to a high-temperature environment at a temperature of about 750° C. at the maximum and other properties deteriorate when it is exposed to such high-temperature environment, and thus, thermal stability may deteriorate.

The seizure resistance of AlCrN (Aluminum chromium nitride) may not be sufficient, such that molten alloys such as molten aluminum may easily adhere to the surface of a mold and the lifespan of a mold may be reduced and the quality of molded products may deteriorate.

The EGR for improving combustion efficiency includes a flat valve, a shaft, a bush, a washer, and a housing, in which the flat valve and the bush or the washer and the bush may slide at a high temperature. Accordingly, the flat valve may be difficult to open/close due to seizure and wear of the washer or the flat valve with the bush at a high temperature, and the quality such as noise and output may deteriorate by wear of the flat valve.

Inconel713C or SUS420J2 may be a material of the parts of the EGR in the related art but it may lack of high-temperature hardness, so it is vulnerable to wear. A CrN coating layer has been used to solve these problems, but it may not have sufficient heat resistance at a temperature of about 500° C. or greater, such that the hardness decreases and seizure is caused by friction and wear, thereby accelerating wear.

In addition, a TiAlN coating layer may not satisfy composite requirement properties such as heat resistance, wear resistance, seizure resistance, and low friction at a temperature of about 700° C.

### SUMMARY OF THE INVENTION

In a preferred aspect, the present invention provides a high-temperature low-friction coating layer that may improve turbo-lag by changing the quality of the material for a turbine wheel and durability of the parts operating at a high temperature in the exhaust system of an engine. The high-temperature low-friction coating layer may improve heat resistance, fatigue resistance, low-friction ability, and seizure resistance, by applying a coating layer to the turbine wheel of a turbocharger and the parts sliding at a high temperature in the exhaust system of an engine. Particularly, the coating layer may include: a CrN bonding layer on a base material, a TiAlCrYN nano-multi-support layer on the CrN bonding layer, and a TiAlCrYCN nano-multi-function layer on the TiAlCrYN nano-multi-support layer. The present invention also provides a method of forming the coating layer.

In an exemplary embodiment, a high-temperature low-friction coating layer may include: a CrN-bonding layer disposed on a nitrified base material to improve close-contact ability of a coating layer; a TiAlCrYN nano-multi-support layer disposed on the CrN-bonding layer to achieve heat resistance, fatigue resistance, wear resistance, and toughness of the coating layer; and a TiAlCrYCN nano-multi-function layer disposed on the TiAlCrYN nano-multi-support layer to achieve heat resistance, oxidation resistance, seizure resistance, toughness, and low-friction ability of the coating layer.

In particular, the thickness of the TiAlCrYN nano-multi-support layer 120 may be in a range of about 0.5 to 10 μm and the thickness of the TiAlCrYCN nano-multi-function layer 130 may be in a range of about 0.5 to 10 μm.

The yttrium and carbon (YC) content in the TiAlCrYCN nano-multi-function layer 130 may be in a range of about 2 to 30 at. % based on the whole atoms of the TiAlCrYCN nano-multi-function layer 130.

The atomic ratio of titanium, aluminum and chromium (Ti:Al:Cr) of the TiAlCrYN nano-multi-support layer 120 may be about 1:1:1.

In an exemplary embodiment, a method of forming a high-temperature low-friction coating layer may include steps of: applying vacuum inside of a chamber, generating a plasma state of argon ions by injecting an argon gas, and then cleansing and activating the surface of a nitrified base material by making argon cation hit against the surface of the base material; injecting a nitrogen gas (N₂) into the chamber to supply N ions and then forming a CrN bonding layer on the surface of the base material by using a Cr target supplying Cr ions; forming a TiAlCrYN nano-multi-support layer on the CrN bonding layer by using a TiAl target supplying TiAl ions, the Cr target supplying Cr ions, and a Y target supplying Y ions; and further injecting an acetylene gas (C₂H₂) into the chamber to supply C ions and then forming the TiAlCrYCN nano-multi-function layer on the TiAlCrYN nano-multi-support layer by using the TiAl target supplying TiAl ions, the Cr target supplying Cr ions, and the Y target supplying Y ions.

In the forming of the TiAlCrYN nano-multi-support layer, the TiAlCrYN nano-multi-support layer may be formed in about 0.5 to 10 μm thick, and in the forming of TiAlCrYCN nano-multi-function layer, the TiAlCrYCN nano-multi-function layer may be formed in about 0.5 to 10 μm thick.

In the forming of a TiAlCrYCN nano-multi-function layer, an YC content in the TiAlCrYCN nano-multi-function layer may be in a range of about 2 to 30 at. % based on the whole atoms of the TiAlCrYCN nano-multi-function layer 130.

In the forming of a TiAlCrYN nano-multi-support layer 120, the atomic ratio of Ti:Al:Cr in the TiAlCrYN nano-multi-support layer 120 may be about 1:1:1.

According to various exemplary embodiments of the present invention, the high-temperature low-friction coating layer may have improved high-temperature stability, high-temperature seizure resistance, and high-temperature friction wear resistance, such that the wear amount may be reduced and the lifespan of parts sliding at a high temperature, such as the turbine wheel of a turbocharger, a high-temperature parts, the part sliding at a high temperature in an engine and an exhaust system, an aluminum die-casting mold, and a hot stamping mold, may increase.

Accordingly, turbo-lag may be improved because weight such as a turbine wheel may be reduced. Further, the coating layer of the present invention may be applied to a heat shield, a vane upper ring, a cage, a stud, an inside lever, a roller spacer, and a bolt, which are made of high-temperature high-cost materials of a turbocharger, and improve their properties. Furthermore, the lifespan of a high-temperature mold may be improved.

It is understood that a “coating layer” as referred to herein may itself comprise multiple layers, for example, as discussed above, a low-friction coating layer may comprise 1) a CrN bonding layer, 2) a TiAlCrYN nano-multi-support layer, and 3) a TiAlCrYCN nano-multi-function layer.

Further provided are parts such as a turbine wheel, a turbocharger, or aluminum die-casting molds that comprise a coating layer of the invention as disclosed herein.

Still further provided are vehicles including automotive vehicles that comprise a part that contains a coating layer of the invention as disclosed herein.

Other aspects of the invention are discussed infra.

### BRIEF DESCRIPTION OF THE DRAWINGS

FIG. 1 illustrates a cross-sectional view of an exemplary coating layer, comprising base material, a CrN bonding layer, a TiAlCrYN nano-multi-support layer, and a TiAlCrYCN nano-multi-function layer according to an exemplary embodiment of the present invention.

FIG. 2 illustrates an exemplary configuration of physical vapor deposition (PVD) equipment for forming an exemplary coating layer according to an exemplary embodiment of the present invention.

FIGS. 3 to 5 show photographic views of exemplary specimens according to exemplary embodiments of the present invention.

FIGS. 6 to 8 show photographic views of test results of high-temperature seizure on exemplary specimens according to exemplary embodiments of the present invention.

### DETAILED DESCRIPTION

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the terms to describe most appropriately the best method he or she knows for carrying out the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The present invention will be described in detail hereafter.

The present invention relates to a high-temperature low-friction coating layer and a method of forming the coating layer. In one aspect, the present provides a high-temperature low-friction coating layer for improving heat resistance, fatigue resistance, low-friction ability, and seizure resistance, for example, of the turbine wheel of a turbocharger and the parts sliding at a high temperature in the exhaust system of an engine of a vehicle.

FIG. 1 shows a cross-sectional view of an exemplary coating layer including a nitrified base material 100, a CrN bonding 110, a TiAlCrYN nano-multi-support layer 120, and a TiAlCrYCN nano-multi-function layer 130. In an exemplary embodiment, the high-temperature low-friction coating layer of the present invention may include: the CrN bonding layer 110 disposed on the nitrified base material 100 to improve close-contact ability of a coating layer; the TiAlCrYN nano-multi-support layer 120 disposed on the CrN bonding layer 110 to achieve heat resistance, fatigue resistance, wear resistance, and toughness of the coating layer; and the TiAlCrYCN nano-multi-function layer 130 disposed on the TiAlCrYN nano-multi-support layer 120 to achieve heat resistance, oxidation resistance, seizure resistance, toughness, and low-friction ability of the coating layer.

(1) CrN Bonding Layer 110

The CrN bonding 110, as used herein, may improve a bonding force between the base material 110 and the TiAlCrYN nano-multi-support layer 120. The CrN bonding layer 110 may also reduce and adjust residual stress in the coating layer, and improves toughness, fatigue resistance, and shock resistance.

(2) TiAlCrYN Nano-Multi-Support Layer 120

The TiAlCrYN nano-multi-support layer 120, as used herein, may provide improved heat resistance, fatigue resistance, wear resistance, seizure resistance, and toughness to the coating layer. In particular, when the coating layer is exposed to a high temperature, yttrium (Y) may permeate initially into the base of the coating layer and prevent permeation of other components by functioning as a diffusion blocker, such that seizure resistance and toughness of the coating layer may be improved.

The thickness of the TiAlCrYN nano-multi-support layer 120 may be in a range of about 0.5 to 10 μm. When the thickness of the TiAlCrYN nano-multi-support layer 120 is less than about 0.5 μm, it may be vulnerable to local loads, such that the coating layer may be separated, when a load is applied to the coating layer. On the contrary, when the thickness of the TiAlCrYN nano-multi-support layer 120 is greater than about 10 μm, the internal pressure of the coating layer may increase, such that the toughness, hardness, and young's modulus of the coating layer may decrease and the processing time considerably may increase, thereby reducing economic efficiency.

The atomic ratio of Ti:Al:Cr in the TiAlCrYN nano-multi-support layer 120 may be about 1:1:1.

The TiAlCrYN nano-multi-support layer 120 may be a multiple nano-layer configuration formed by alternately overlapping a TiAlN nano-layer and a CrYN nano-layer.

(3) TiAlCrYCN Nano-Multi-Function Layer 130

The TiAlCrYCN nano-multi-function layer 130, as used herein, may provide improved heat resistance, oxidation resistance, seizure resistance, toughness, and low-friction ability to the coating layer. As described above, when the coating layer is exposed to a high temperature, yttrium (Y) may permeate initially into the base of the coating layer and prevent permeation of other components by functioning as a diffusion blocker, such that it may improve seizure resistance and toughness of the coating layer. In addition, carbon (C) may improve seizure resistance, chemical resistance, low-friction ability, and wear resistance together with yttrium (Y).

The thickness of the TiAlCrYCN nano-multi-function layer 130 may be in a range of about 0.5 to 10 μm. When the thickness of the TiAlCrYCN nano-multi-function layer 130 is less than about 0.5 μm, it may be vulnerable to local loads, such that the coating layer may be separated, when a load is applied to the coating layer. On the contrary, when the thickness of the TiAlCrYCN nano-multi-function layer 130 is greater than about 10 μm, the internal pressure of the coating layer may increase, such that the toughness, hardness, and young's modulus of the coating layer may decrease and the processing time may substantially increase, thereby reducing economical efficiency.

Based on the whole atoms of the TiAlCrYCN nano-multi-function layer 130, the Y content and the C content in the TiAlCrYCN nano-multi-function layer 130 may be in a range of about 1 to 10 at. % and of about 1 to 20 at. %, respectively. As such, the YC content in the TiAlCrYCN nano-multi-function layer 130 may be in a range of about 2 to 30 at. % to the whole atoms of the TiAlCrYCN nano-multi-function layer 130. When the contents of YC is less than about 2 at. %, the low-friction ability and seizure resistance may decrease, and when the content of YC is greater than about 30 at. %, the hardness and heat resistance may decrease.

The TiAlCrYCN nano-multi-function layer 130 may be a multiple nano-layer configuration formed by alternately overlapping a TiAlN nano-layer and a CrYCN nano-layer.

The high-temperature low-friction coating layer of the present invention may be applied to a heat shield, a vane upper ring, a cage, a stud, an inside lever, a roller spacer, and a bolt, which are made of high-temperature high-cost materials of a turbocharger, and may improve their properties. Further, the coating layer may be applied to the exhaust system of an engine that is a part sliding at a high temperature, and improve the desired lifespan of the engine.

In another aspect, the present invention provides a method of forming a high-temperature low-friction coating layer.

The method of coating the surface of a metal base material with a coating layer may be classified into physical vapor deposition (PVD) and chemical vapor deposition (CVD).

PVD is a dry type process that connects a cathode to a target base material, supplies gaseous ionized metal, and deposits the ionized metal to a surface of the base material by using electric attraction. Accordingly, uniformly coat on the surface of a base material may be obtained and close-contact force may increase using micro-ion particles.

Accordingly, PVD using an arc, high power impulse magnetron sputtering (HIPIMS), and inductive coupled plasma (ICP) may be use to achieve nano-size particles of a coating layer and high-speed coating.

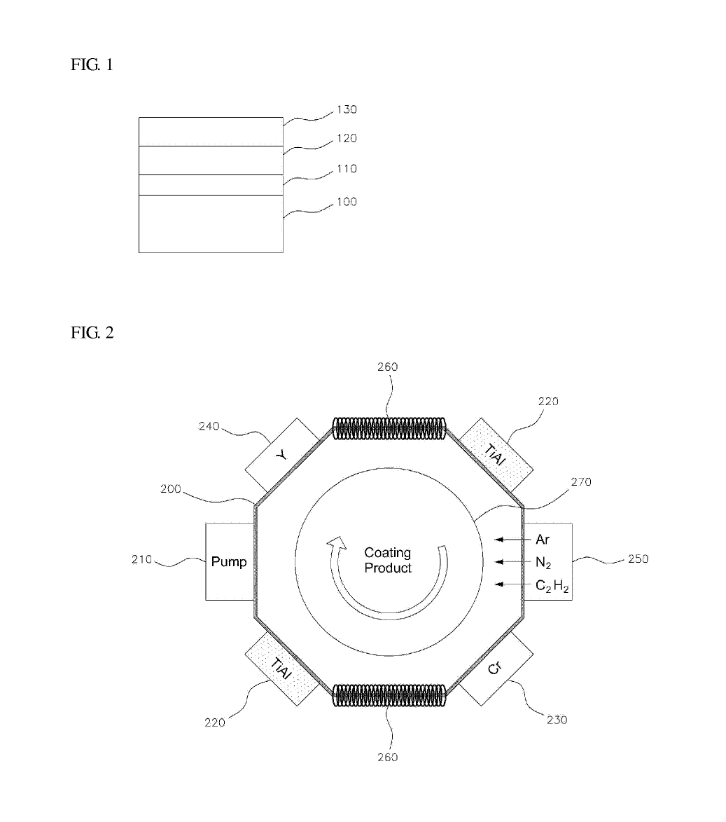

FIG. 2 illustrates an exemplary configuration of PVD equipment for forming a coating layer of the present invention. As illustrated in FIG. 2, the PVD equipment may include: a chamber 200; a pump 210, a TiAl target 220, a Cr target 230, a Y target 240, a gas injection unit 250, and a heating unit 260 that are disposed on the chamber 200; and a rotary holder 270 where a nitrified base material 100 may be placed inside the chamber 200.

A method of forming the high-temperature low-friction coating layer using the PVD equipment may include: applying vacuum inside of the chamber 200, generating a plasma state of argon ions by injecting an argon gas, and then cleansing and activating the surface of the base material 100 by making argon cation hit against the surface of the nitrified base material 100; injecting a nitrogen gas (N₂) into the chamber 200 to supply N ions and then forming the CrN bonding layer 110 on the surface of the base material 100 by using the Cr target 230 supplying Cr ions; forming the TiAlCrYN nano-multi-support layer 120 on the CrN bonding layer 110 by using the TiAl target 220 supplying TiAl ions, the Cr target 230 supplying Cr ions, and the Y target 240 supplying Y ions; and injecting an acetylene gas (C₂H₂) into the chamber 200 to supply C ions and then forming the TiAlCrYCN nano-multi-function layer 130 on the TiAlCrYN nano-multi-support layer 120 by using the TiAl target 220 supplying TiAl ions, the Cr target 230 supplying Cr ions, and the Y target 240 supplying Y ions.

When the TiAlCrYN nano-multi-support layer 120 is formed, the TiAlCrYN nano-multi-support layer 120 may be formed in about 0.5 to 10 μm thick, and when the TiAlCrYCN nano-multi-function layer 130 is formed, the TiAlCrYCN nano-multi-function layer 130 may be formed in about 0.5 to 10 μm thick.

In detail, as a pre-process of coating, the inside of the chamber 200 may be in vacuum state by the pump 210 and then a plasma state of argon ions may be generated by injecting an argon gas through the gas injection unit 250.

The chamber 200 may be heated by the heating unit 260 and the surface of the base material 100 may be cleansed and activated by making the argon cations hit against the surface of the base material 100 by applying a bias voltage to the mold.

Subsequently, nitrogen atmosphere may be formed by injecting a nitrogen gas (N₂) into the chamber 200 through the gas injection unit 250 and the CrN bonding layer 110 which may reduce and adjust residual stress due to coating and improve toughness, fatigue resistance and shock resistance may be formed on the surface of the base material 100, using the Cr target 230 supplying Cr ions.

The TiAlCrYN nano-multi-support layer 120 may be formed at a thickness of about 0.5 to 10 μm on the CrN bonding 110, using the TiAl target 220 supplying TiAl ions, the Cr target 230 supplying Cr ions, and the Y target 240 supplying Y ions. In particular, the atomic ratio of Ti:Al:Cr may be about 1:1:1.

An acetylene gas (C₂H₂) may be additionally injected through the gas injection unit 250 to supply C other than the nitrogen gas (N₂), and then the TiAlCrYCN nano-multi-function layer 130 may be formed at a thickness of about 0.5 to 10 μm on the TiAlCrYN nano-multi-support layer 120, using the TiAl target 220 supplying TiAl ions, the Cr target 230 supplying Cr ions, and the Y target 240 supplying Y ions.

Based on the whole atoms in the TiAlCrYCN nano-multi-function layer 130, the Y content in the TiAlCrYCN nano-multi-function layer 130 may be of about 1 to 10 at. % and C content may be of about 1 to 20 at. %, and the YC content to the whole atom in the TiAlCrYCN nano-multi-function layer 130 may be determined to be of about 2 to 30 at. %.

### EXAMPLE

The present invention will be described hereafter in more detail through embodiments. The embodiments are only examples of the present invention and it would be apparent to those skilled in the art that the scope of the present invention is not construed as being limited to the embodiments.

In order to compare properties of the high-temperature low-friction coating layer according to the present invention, specimens of Example 1, Comparative Example 1 and Comparative Example 2 were manufactured by PVD and properties thereof were compared.

TABLE 1

| | | Comparative | Comparative |
|---|---|---|---|
| Item | Example 1 | Example 1 | Example 2 |
| Surface coating | TiAlCrYCN | TiAlN | TiAlCrSiCN |
| layer | | | |
| Thickness of entire | 9.8 | 10.2 | 10.3 |
| coating layer (μm) | (2.6 CrN—4.1 | (4.9 CrN—5.3 | (4 CrN—4.1 |
| | TiAlCrYN—3.1 | TiAlN) | TiAlCrN—2.2 |
| | TiAlCrYCN) | | TiAlCrSiCN) |
| Bonding force (N) | 50 or more | 50 or more | 50 or more |
| (room-temperature) | 2740 | 2940 | 3050 |
| Hardness (HV) | | | |
| High-temperature | 2712 | 2147 | 2752 |
| hardness (HV) | | | |
| under 900° C./6 hr | | | |
| Hardness reduction | 1.0 | 27.0 | 9.8 |
| rate (%) | | | |

Table 1 shows comparison of properties of Example 1 including a TiAlCrYCN coating layer, Comparative Example 1 including a TiALN coating layer of the related art and Comparative Example 2 including a TiAlCrSiCN coating layer.

The bonding force was calculated by making a line of groove on the coating layer surfaces of the specimens of Example 1, Comparative Example 1 and Comparative Example 2 by increasing a load with a diamond tip, and then measuring the load applied until the coating layers were separated first.

The thicknesses of the coating layers were measured from craters formed by pressing a steel ball into the specimens of Example 1, Comparative Example 1 and Comparative Example 2.

The hardness was measured by calculating grooves formed by pressing an intender having a depth of about 0.7 μm into the specimens of Example 1, Comparative Example 1, and Comparative Example 2 under a load of about 0.05 N.

The high-temperature hardness was measured by leaving the specimens of Example 1, Comparative Example 1 and Comparative Example 2 in an oven at a temperature of about 900° C. for about six hours, cooling them to the room temperature, and then using the same way as the hardness measured before, and the reduction rate of the hardness and the high-temperature hardness measured at a high temperature was measured.

According to the result of the tests on Example 1, Comparative Example 1 and Comparative Example 2, the hardness measured at the room temperature of Example 1 including a TiAlCrYCN layer of the present invention was less than those of Comparative Example 1 and Comparative Example 2, and the difference between the hardness measured at a high temperature of about 900° C. and the hardness measured at the room temperature was the least and maintained at a level equal to the high-temperature hardness in Comparative Example 2. Accordingly, high-temperature stability of Example 1 may be substantially improved.

In particular, the TiAlCrYCN nano-multi-function coating layer of the present invention as shown in Example 1 may have high-temperature heat resistance at a temperature of about 900° C. and high-temperature stability or reduction rate of hardness increased twenty seven times that of the TiAlN layer and about ten times that of the TiAlCrSiCN layer.

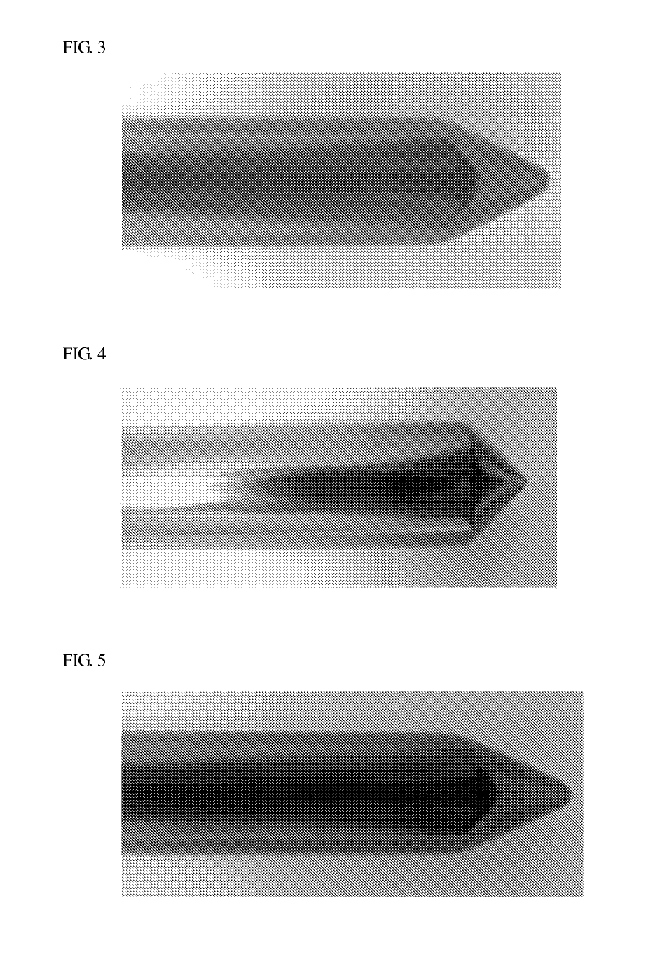

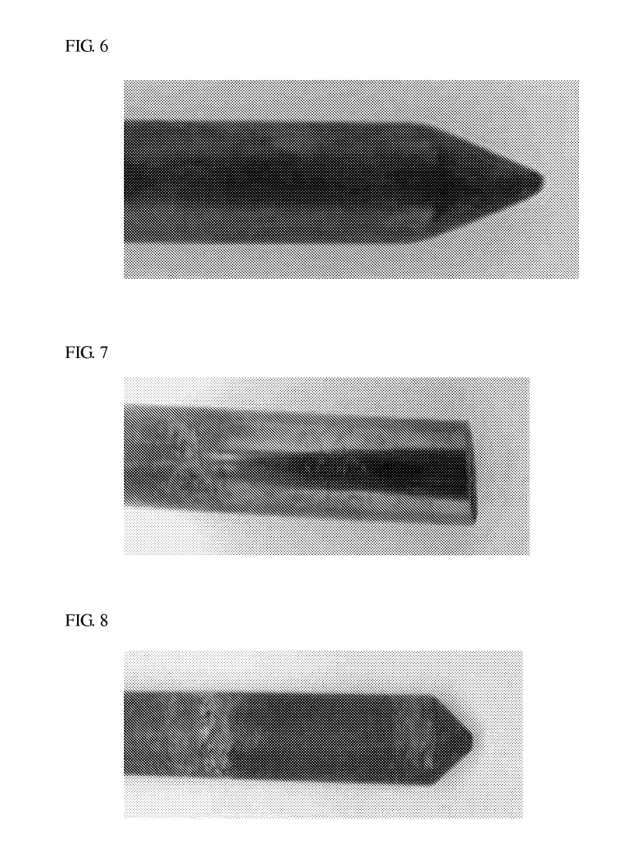

FIGS. 3 to 5 show photographic views of exemplary specimens of Example 1, Comparative Example 1, and Comparative Example 2, respectively, and FIGS. 6 to 8 shows photographic views of the specimens of Example 1, Comparative Example 1, and Comparative Example 2 after a high-temperature seizure test of dipping and rotating in molten ADC12 (aluminum) at a temperature of about 850° C. for a predetermined time and then cleansing them with sodium hydroxide (NaOH) to remove seized aluminum.

As shown in FIGS. 3-8, after high-temperature seizure test, the specimen of the Comparative Example 1 had a substantial amount of seized portions and the seized portions were dissolved after cleansing with sodium hydroxide. The specimen of Comparative Example 2 had a less amount of seized portions and a small amount of the seized portions were dissolved after cleansing, but surface defects were generated substantially.

However, in Example 1 according to an exemplary embodiment of the present invention, seized portion was barely formed and no dissolved portion and surface defect was found since seizure resistance of the base material was significantly improved by the coating layer according to the present invention, particularly, the TiAlCrYCN nano-multi-function layer.

TABLE 2

| | | Comparative | Comparative |
|---|---|---|---|
| Item | Example 1 | Example 1 | Example 2 |
| Surface coating layer | TiAlCrYCN | TiAlN | TiAlCrSiCN |
| Amount of wear of | 1.52 | 34.2 | 10.3 |
| coating layer (disc) | | | |
| (mg) | | | |
| Amount of wear of | 3.45 | 94.6 | 31.4 |
| counter-material | | | |
| (pin) | | | |
| (mg) | | | |
| Total wear amount | 4.97 | 128.8 | 41.7 |
| (mg) | | | |
| Friction coefficient | 0.28 | 0.75 | 0.39 |
| of coating layer | | | |

Table 2 shows comparison of high-temperature friction wear tests on Example 1, Comparative Example 1 and Comparative Example 2.

The high-temperature friction wear test was conducted by measuring the friction amount and the friction coefficient between the coating layers (disc) and the pins (WC material) of Example 1, Comparative Example 1 and Comparative Example 2, using a pin-on-disc friction wear tester. The test conditions were a load of about 20 N, a distance of about 2 km, a speed of about 0.1 m/s, and a temperature of about 850° C.

According to the high-temperature friction wear test, the wear amount of the coating layer (disc) and the wear amount of the counter-material (pin) in Example 1 was considerably less than those of Comparative Example 1 and Comparative Example 2, and the friction coefficient of Example 1 was also the least.

Accordingly, the high-temperature friction wear resistance of the coating layer according to an exemplary embodiment of present invention may be substantially improved from the fact that the high-temperature friction wear of Example 1 including the TiAlCrYCN nano-multi-function layer of the present invention was the least and the friction coefficient is the least.

In detail, the high-temperature seizure resistance at a temperature of about 850° C. of the TiAlCrYCN nano-multi-function coating layer of Example 1 according to an exemplary embodiment of the present invention was remarkably improved, as compared with the TiAlN layer of Comparative Example 1 and the TiAlCrSiCN layer of Comparative Example 2. As such, the high-temperature low-friction ability and the wear resistance at a temperature of about 850° C. of Example were improved by about twenty six times in comparison to Comparative Example 1 and by about 8.4 times or greater in comparison to Comparative Example 2, on the basis of the wear amount. Further, the high-temperature low-friction ability and the wear resistance at a temperature of about 850° C. of Example 1 were improved by about 2.7 times and by about 1.4 times or greater in comparison to Comparative Example 1 and Comparative Example 2, respectively, on the basis of the friction coefficient.

TABLE 3

| | | | Comparative | Comparative | Comparative | Comparative |
|---|---|---|---|---|---|---|
| Item | Example 1 | Example 2 | Example 3 | Example 4 | Example 5 | Example 6 |
| Thickness of | 8 | 10 | 0.4 | 12 | 8 | 8 |
| TiAlCrYCN | | | | | | |
| function layer | | | | | | |
| (μm) | | | | | | |
| Thickness of | 8 | 10 | 8 | 8 | 0.4 | 12 |
| TiAlCrYN | | | | | | |
| support layer | | | | | | |
| (μm) | | | | | | |
| Index of elasticity | 0.086 | 0.082 | 0.091 | 0.064 | 0.075 | 0.064 |
| (H/E) | | | | | | |
| Coating time (h) | 8 | 10 | 4.2 | 13 | 4.4 | 13 |
| Separation of | No | No | Yes | No | Yes | No |
| coating under | | | | | | |
| local load | | | | | | |

H: Hardness
E: Young's modulus

Table 3 shows comparison of index of elasticity and coating time according to the thickness of the TiAlCrYCN function layer and the TiAlCrYN support layer. Example 2 and Comparative Examples 3-6 in Table 3 have same configuration of Example 1, but the thicknesses of the TiAlCrYCN function layer or the TiAlCrYN support layer are different.

Further, the thickness of the TiAlCrYCN function layer is less than about 0.5 μm in Comparative Example 3, while the thickness of the TiAlCrYCN function layer is greater than about 10 μm in Comparative Example 4. Further, the thickness of the TiAlCrYN support layer is less than about 0.5 μm in Comparative Example 5, while the thickness of the TiAlCrYN support layer is greater than about 10 μm in Comparative Example 6.

Since the thicknesses of the TiAlCrYCN function layer and the TiAlCrYN support layer in Examples 1-2 range from about 0.5 μm to about 10 μm according to an exemplary embodiment of the present invention, the index of elasticity exhibiting toughness was greater than those of Comparative Examples 4-6 and less than that of Comparative Example 3. Meanwhile, in Comparative Example, 3 the coating was separated under a local load.

The indexes of elasticity (H/E) in Comparative Examples 4-6 are less than those in Examples 1-2 because the thickness of the TiAlCrYCN function layer or the TiAlCrYN support layer was greater than 10 μm and stress increased due to an increase in internal pressure.

When a local load is applied to the coating layers in Comparative Examples 3-5, the coating may separate because the coating layers may not resist a load applied, when the thickness the TiAlCrYCN function layer or the TiAlCrYN support layer is less than 0.5 μm.

The coating time of the TiAlCrYCN function layer or the TiAlCrYN support layer increases in proportion to the thickness of the coating layer within the range of about 0.5 to 10 μm according to an exemplary embodiment of the present invention. However, when the thickness of the coating layer is greater than about 10 μm, coating time of about 50% greater may be further required. Accordingly, the thickness of about 0.5 to 10 μm of the TiAlCrYCN function layer or the TiAlCrYN support layer may be optimal with respect to the cost.

TABLE 4

| | | Comparative | Comparative |
|---|---|---|---|
| Item | Example 1 | Example 7 | Example 8 |
| YC content of | 15 | 1 | 32 |
| TiAlCrYCN | | | |
| function layer (at. %) | | | |
| High-temperature | 0.48 | 0.54 | 0.35 |
| friction coefficient at | | | |
| 850° C. | | | |
| (room-temperature) | 2740 | 2886 | 2421 |
| Hardness (HV) | | | |
| High-temperature | 2712 | 2646 | 2164 |
| hardness (HV) under | | | |
| 900° C./6 hr | | | |
| Hardness reduction | 1.0 | 8.3 | 10.6 |
| rate (%) | | | |
| Test of seizure on | No surface defect | Too much | No surface |
| molten aluminum | | surface defect | defect |
| under 850° C./30 hr | | Too much | |
| | | seizure | |
| Remark | Excellent low- | Low-friction | Hardness |
| | friction ability, | ability and | and heat |
| | seizure resistance, | seizure | resistance |
| | hardness, and | resistance | reduced |
| | heat resistance | reduced | |

Table 4 shows comparison of high-temperature friction coefficient, hardness, high-temperature hardness, hardness reduction rate, and seizure test result according to the YC content in the TiAlCrYCN function layer.

In Comparative Examples 7-8, the configurations thereof is same as that in Example 1, but the YC content or the total contents of Y (yttrium) and C (carbon) in the TiAlCrYCN function layer is out of the range of about 2 to 30 at. % to the whole atoms of the TiAlCrYCN nano-multi-function layer.

In detail, the low-friction ability, heat resistance, and seizure resistance were substantially improved in Example 1 having the YC content of the TiAlCrYCN function layer within the range according to an exemplary embodiment of the present invention. As compared to Comparative Examples 7-8, in Example 1, the friction coefficient was less, the high-temperature was greater, the hardness reduction rate was the least, and no surface defect was found in a molten aluminum seizure test.

In contrast, in Comparative Example 7 having the YC content in the TiAlCrYCN function layer less than about 2 at. %, the friction coefficient was greater than that of Example 1, the low-friction ability is less and surface defect of the specimen and seizure are generated substantially in the molten aluminum seizure test, and thus the seizure resistance is inferior.

Also, in Comparative Example 8 having the YC content in the TiAlCrYCN function layer greater than about 30 at. %, the friction coefficient is less than that of Example 1, the low-friction ability is slightly improved from Example 1, but the hardness is inferior and the hardness reduction ratio greatly decreases, and thus the high-temperature stability is inferior.

Although the present invention was described with reference to detailed embodiments, the present invention is not limited thereto. The embodiments described above may be changed or modified by those skilled in the art without departing from the scope of the present invention and may be change and modified in various ways within the range equal to the spirit of the present invention and the claims to be described below.

What is claimed is:

1. A high-temperature low-friction coating layer, comprising:
a CrN bonding layer disposed on a nitrified base material to improve close-contact ability of the coating layer;
a TiAlCrYN nano-multi-support layer disposed on the CrN-bonding layer to achieve heat resistance, fatigue resistance, wear resistance, and toughness of the coating layer; and
a TiAlCrYCN nano-multi-function layer disposed on the TiAlCrYN nano-multi-support layer to achieve heat resistance, oxidation resistance, seizure resistance, toughness, and low-friction ability of the coating layer.

2. The coating layer of claim 1, wherein the thickness of the TiAlCrYN nano-multi-support layer 120 is in a range of about 0.5 to 10 μm, and
the thickness of the TiAlCrYCN nano-multi-function layer is in a range of about 0.5 to 10 μm.

3. The coating layer of claim 1, wherein an YC content in the TiAlCrYCN nano-multi-function layer is in a range of about 2 to 30 at. % based on the whole atoms of the TiAlCrYCN nano-multi-function layer.

4. The coating layer of claim 1, wherein an atomic ratio of Ti:Al:Cr in the TiAlCrYN nano-multi-support layer is about 1:1:1.

5. A method of forming a high-temperature low-friction coating layer, comprising:
applying vacuum inside of a chamber, generating a plasma state of argon ions by injecting an argon gas, and then cleansing and activating the surface of a nitrified base material by making argon cation hit against the surface of the base material;
injecting a nitrogen gas (N₂) into the chamber to supply N ions and then forming a CrN bonding layer on the surface of the base material by using a Cr target supplying Cr ions;
forming a TiAlCrYN nano-multi-support layer on the CrN bonding layer by using a TiAl target supplying TiAl ions, the Cr target supplying Cr ions, and a Y target supplying Y ions; and
injecting an acetylene gas (C₂H₂) into the chamber to supply C ions and then forming a TiAlCrYCN nano-multi-function layer on the TiAlCrYN nano-multi-support layer by using the TiAl target supplying TiAl ions, the Cr target supplying Cr ions, and the Y target supplying Y ions.

6. The method of claim 5, wherein in the forming of a TiAlCrYN nano-multi-support layer, the TiAlCrYN nano-multi-support layer is formed in about 0.5 to 10 μm thick, and
in the forming of a TiAlCrYCN nano-multi-function layer, the TiAlCrYCN nano-multi-function layer is formed in about 0.5 to 10 μm thick.

7. The method of claim 5, wherein in the forming of a TiAlCrYCN nano-multi-function layer, an YC content in the TiAlCrYCN nano-multi-function layer is of about 2 to 30 at. % based the whole atoms of the TiAlCrYCN nano-multi-function layer.

8. The method of claim 5, wherein in the forming of a TiAlCrYN nano-multi-support layer, the atomic ratio of Ti:Al:Cr in the TiAlCrYN nano-multi-support layer is of about 1:1:1.

9. A part that comprises a coating layer of claim 1.

10. A part of claim 9 that is a turbocharger, a turbine wheel, or aluminum die-casting mold.

11. A vehicle comprising a part of claim 9.
